(19) United States
(12) Patent Application Publication
(10) Pub. No.: US 2013/0230998 A1
(43) Pub. Date: Sep. 5, 2013

(54) MEMORY DEVICE LATCHING SYSTEM

(71) Applicants: Darren B. Pav, Round Rock, TX (US); Brian T. Whitman, University Place, WA (US)

(72) Inventors: Darren B. Pav, Round Rock, TX (US); Brian T. Whitman, University Place, WA (US)

(73) Assignee: Dell Products L.P., Round Rock, TX (US)

(21) Appl. No.: 13/412,068

(22) Filed: Mar. 5, 2012

(51) Int. Cl. H01R 13/62; H05K 3/30; H01R 43/00

(52) U.S. Cl. 439/296; 29/825; 29/832

(57) ABSTRACT

A memory device latching system includes a processor. A plurality of memory devices are coupled to the processor through respective memory sockets. A first memory socket includes a first latch member having a first latch actuation member and defining a second latch member channel. A second memory socket includes a second latch member having a second latch actuation member and defining a first latch member channel. The first memory socket and the second memory socket are mounted to a circuit board such that the first latch end is located adjacent the second latch end, and the first latch member and the second latch member are operable to move to open positions such that at least a portion of the first latch actuation member is located in the first latch member channel and at least a portion of the second latch actuation member is located in the second latch member channel.

### BACKGROUND

The present disclosure relates generally to information handling systems (IHSs), and more particularly to memory device latching system for an IHS.

As the value and use of information continues to increase, individuals and businesses seek additional ways to process and store information. One option is an information handling system (IHS). An IHS generally processes, compiles, stores, and/or communicates information or data for business, personal, or other purposes. Because technology and information handling needs and requirements may vary between different applications, IHSs may also vary regarding what information is handled, how the information is handled, how much information is processed, stored, or communicated, and how quickly and efficiently the information may be processed, stored, or communicated. The variations in IHSs allow for IHSs to be general or configured for a specific user or specific use such as financial transaction processing, airline reservations, enterprise data storage, or global communications. In addition, IHSs may include a variety of hardware and software components that may be configured to process, store, and communicate information and may include one or more computer systems, data storage systems, and networking systems.

The ever-increasing push for smaller yet more powerful IHSs requires that IHSs utilize denser feature sets that maximize the number of storage devices, processors, memory devices, networking devices, expansion devices, and other IHS components in the IHS chassis and/or minimize the volume that those IHS components occupy in the IHS chassis. For example, memory devices in the IHS typically couple to the processor through memory sockets that are mounted to a circuit board and coupled to the processor through the circuit board. In order to minimize the IHS chassis volume, circuit board area, and associated routing utilized for the memory devices, the memory sockets are positioned adjacent each other in rows and columns. However, the adjacent positioning of the memory sockets is limited by the latches on the memory sockets that couple the memory devices to the memory sockets. Conventional memory sockets include latches on each opposing end of the memory socket. The latches pivot about their coupling to the memory socket and away from the memory socket such that the memory device may be positioned in the memory socket. The latches may then be pivoted back towards the memory socket in order to couple the memory device to the memory socket. As discussed above, the memory sockets are typically positioned in rows and columns such that pairs of memory sockets are located on the circuit board end-to-end with their latches adjacent each other. Because the latches on the memory device require a volume adjacent the memory sockets in which to pivot in order to allow the coupling of the memory devices to the memory sockets, there is a minimum spacing between the memory sockets that must be provided so that the latches of adjacent memory sockets will not interfere with each other and prevent the proper functioning of the latches (e.g., by preventing the full pivoting of one or both of the latches such that the memory device may not be positioned in the memory socket) or otherwise provide a negative user experience (e.g., one of the latches may get ‘caught’ or ‘stuck’ underneath the other latch.)

Accordingly, it would be desirable to provide an improved memory device latching system.

### SUMMARY

According to one embodiment, an IHS component latching system includes a first IHS component coupling device having a first latch end including a first latch member, wherein the first latch member includes a first latch actuation member and defines a second latch member channel, and a second IHS component coupling device having a second latch end including a second latch member, wherein the second latch member includes a second latch actuation member and defines a first latch member channel, wherein, with the first latch end on the first IHS component coupling device located adjacent the second latch end on the second IHS component coupling device, the first latch member is operable to move relative to the first latch end and the second latch member is operable to move relative to the second latch end such that at least a portion of the first latch actuation member is located in the first latch member channel and at least a portion of the second latch actuation member is located in the second latch member channel.

### BRIEF DESCRIPTION OF THE DRAWINGS

FIG. 1 is a schematic view illustrating an embodiment of an information handling system.

FIG. 2a is a top view illustrating an embodiment of a plurality of conventional memory sockets on a circuit board.

FIG. 2b is a side view illustrating an embodiment of the plurality of conventional memory sockets on the circuit board of FIG. 2a.

FIG. 2c is a side view illustrating an embodiment of the plurality of conventional memory sockets on the circuit board of FIGS. 2a and 2b with a memory device being coupled to a memory socket.

FIG. 2d is a perspective view illustrating an embodiment of the plurality of conventional memory sockets on the circuit board of FIGS. 2a and 2b with the latches on adjacent memory sockets interfering with each other.

FIG. 3a is a top view illustrating an embodiment of an IHS component latching system.

FIG. 3b is a side view illustrating an embodiment of the IHS component latching system of FIG. 3a.

FIG. 4 is a top view illustrating an embodiment of a latch member on the IHS component latching system of FIGS. 3a and 3b.

FIG. 5a is a flow chart illustrating an embodiment of a method for coupling IHS components to an IHS.

FIG. 5b is a top view illustrating an embodiment of a pair of adjacent latch members on the IHS component latching system of FIGS. 3a and 3b moved to an open position such that the latch members are nested.

FIG. 5c is a top view illustrating an embodiment of the pair of adjacent latch members of FIG. 5b nested.

FIG. 5d is a perspective view illustrating an embodiment of a pair of adjacent latch members on the IHS component latching system of FIGS. 3a and 3b moved to an open position such that the latch members are nested.

FIG. 5e is a side view illustrating an embodiment of a pair of adjacent latch members on the IHS component latching system of FIGS. 3a and 3b moved to a closed position such that the latch members are coupling and securing IHS components to an IHS.

### DETAILED DESCRIPTION

For purposes of this disclosure, an IHS may include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, an IHS may be a personal computer, a PDA, a consumer electronic device, a display device or monitor, a network server or storage device, a switch router or other network communication device, or any other suitable device and may vary in size, shape, performance, functionality, and price. The IHS may include memory, one or more processing resources such as a central processing unit (CPU) or hardware or software control logic. Additional components of the IHS may include one or more storage devices, one or more communications ports for communicating with external devices as well as various input and output (I/O) devices, such as a keyboard, a mouse, and a video display. The IHS may also include one or more buses operable to transmit communications between the various hardware components.

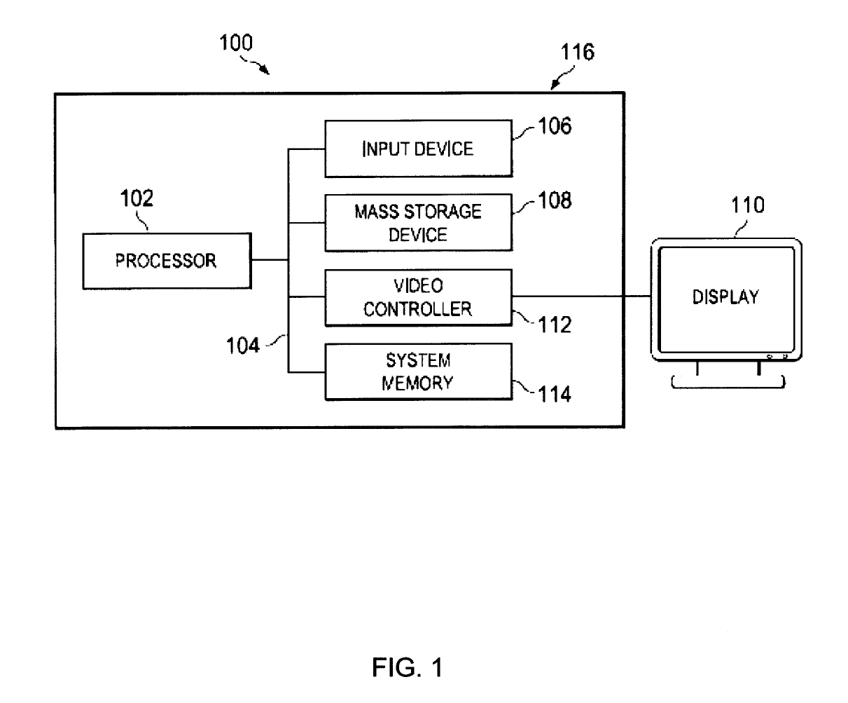

In one embodiment, IHS 100, FIG. 1, includes a processor 102, which is connected to a bus 104. Bus 104 serves as a connection between processor 102 and other components of IHS 100. An input device 106 is coupled to processor 102 to provide input to processor 102. Examples of input devices may include keyboards, touchscreens, pointing devices such as mouses, trackballs, and trackpads, and/or a variety of other input devices known in the art. Programs and data are stored on a mass storage device 108, which is coupled to processor 102. Examples of mass storage devices may include hard discs, optical disks, magneto-optical discs, solid-state storage devices, and/or a variety other mass storage devices known in the art. IHS 100 further includes a display 110, which is coupled to processor 102 by a video controller 112. A system memory 114 is coupled to processor 102 to provide the processor with fast storage to facilitate execution of computer programs by processor 102. Examples of system memory may include random access memory (RAM) devices such as dynamic RAM (DRAM), synchronous DRAM (SDRAM), solid state memory devices, and/or a variety of other memory devices known in the art. In an embodiment, a chassis 116 houses some or all of the components of IHS 100. It should be understood that other buses and intermediate circuits can be deployed between the components described above and processor 102 to facilitate interconnection between the components and the processor 102.

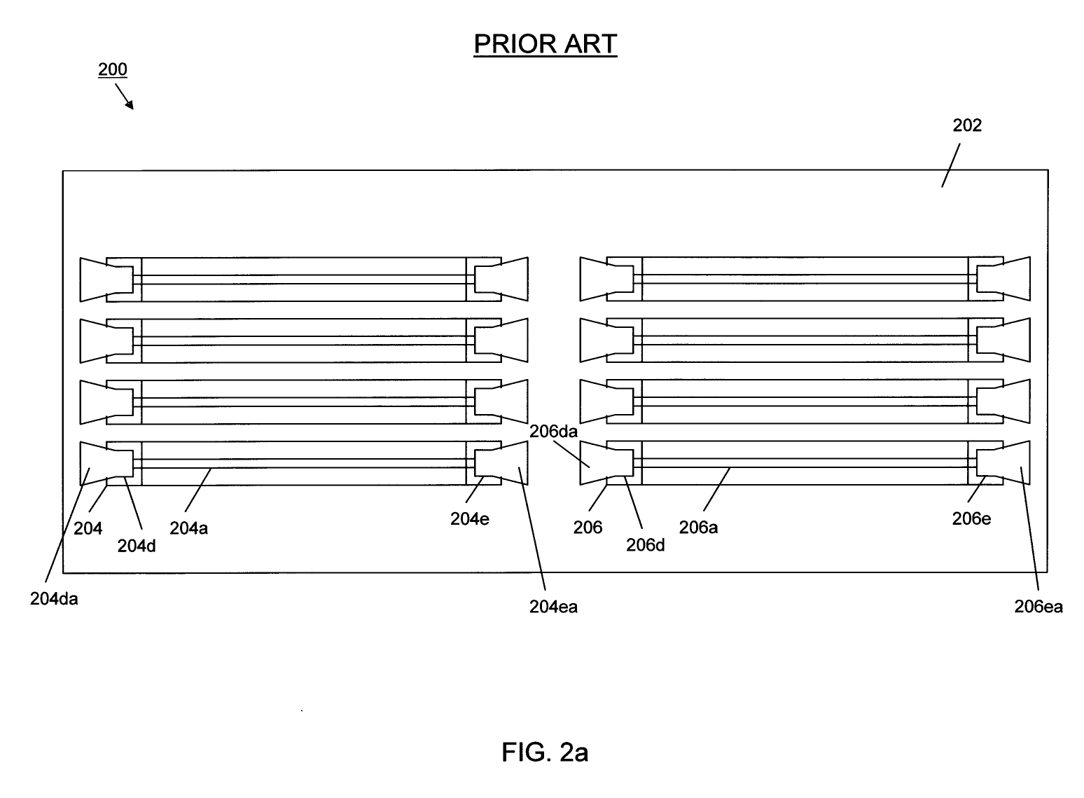

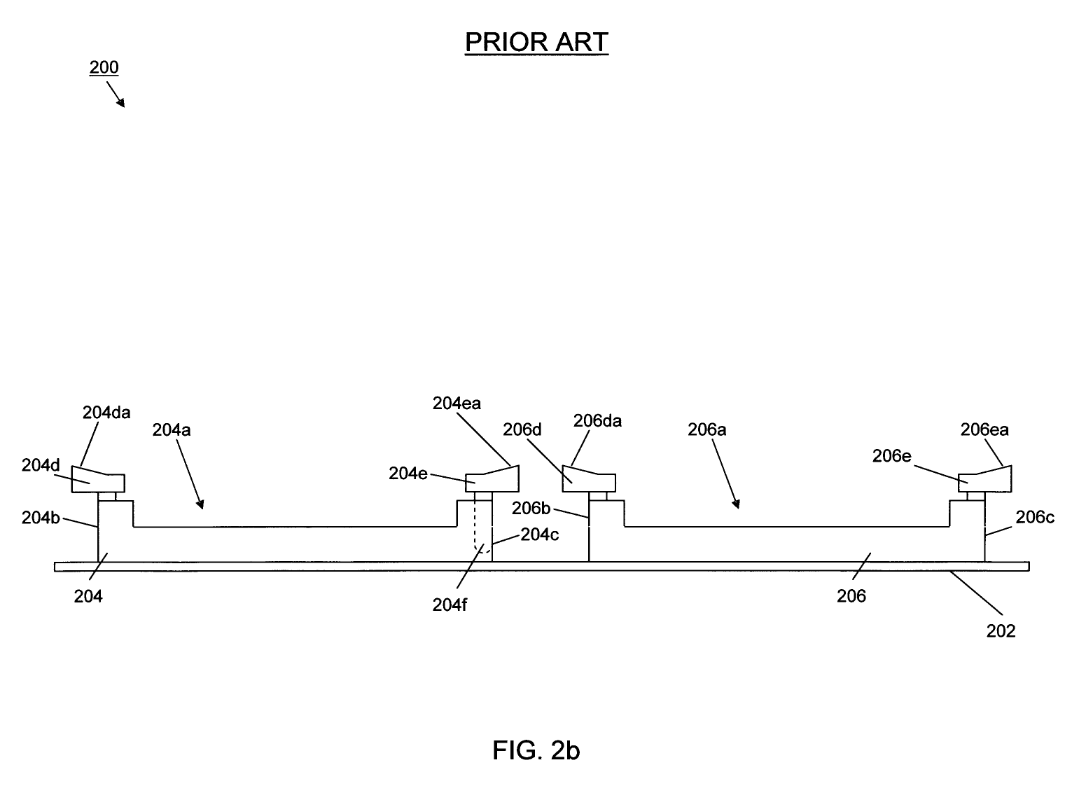

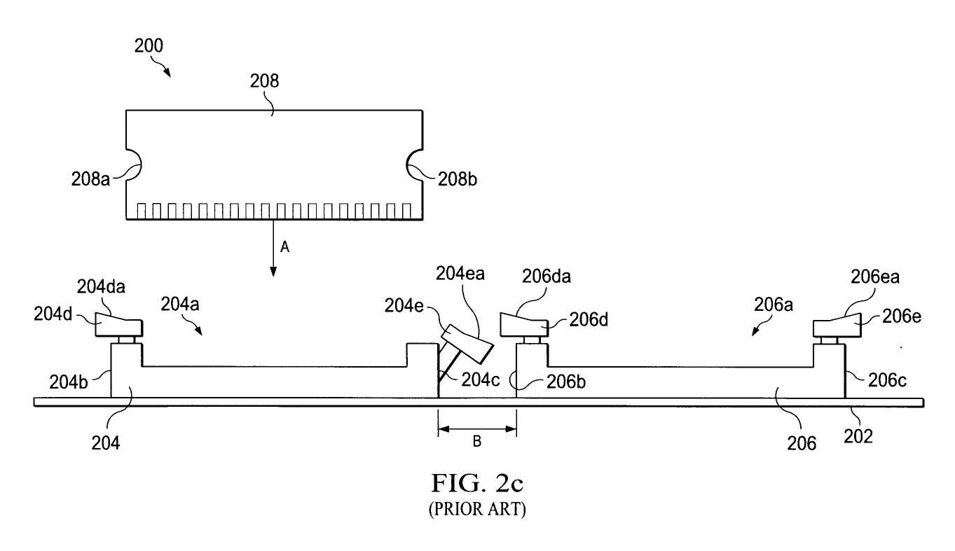

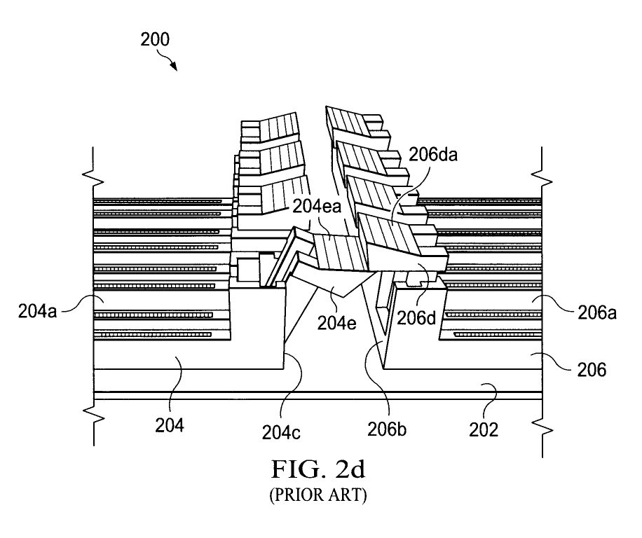

Referring now to FIGS. 2a and 2b, a convention memory device latching system 200 is illustrated. In an embodiment, the memory device latching system 200 may be the system memory 114 included in the IHS described above with reference to FIG. 1. The memory device latching system 200 includes a circuit board 202. A plurality of memory sockets are mounted to the circuit board 202, of which memory sockets 204 and 206 are exemplary. The memory socket 204 defines a memory slot 204a and includes a pair of opposing latch ends 204b and 204c located on opposite sides of the memory slot 204a. A latch member 204d includes an actuation surface 204da and is pivotally coupled to the memory socket 204 on the latch end 204b, and a latch member 204e includes an actuation surface 204ea and is pivotally coupled (e.g., about a pivotal connection 204f) to the memory socket 204 on the latch end 204c. The memory socket 206 defines a memory slot 206a and includes a pair of opposing latch ends 206b and 206c located on opposite sides of the memory slot 206a. A latch member 206d includes an actuation surface 206da and is pivotally coupled to the memory socket 206 on the latch end 206b, and a latch member 206e includes an actuation surface 206ea and is pivotally coupled to the memory socket 206 on the latch end 206c. One of skill in the art will recognize that the memory sockets 204 and 206 may include several features that have not been illustrated or described for clarity of discussion such as, for example, electrical connections on the memory sockets 204 and 206 adjacent the memory slots 204a and 206a, respectively, that are operable to electrically couple a memory device to components on the circuit board 202 such as a processor.

Referring now to FIGS. 2c and 2d, in operation, the convention memory device latching system 200 may be used to couple memory device to IHS components through the circuit board 202. For example, in order to couple a memory device 208 to the memory socket 204, a user may actuate the latch members 204d and 204e by engaging the actuation surfaces 204da and 204ea, respectively, such that the latch members 204d and 204e pivot about their connection to the memory socket 204 and extend from the latch ends 204b and 204c, respectively, to allow the memory device 208 to be moved in a direction A and into the memory slot 204a (while FIG. 2c only illustrates the latch member 204e pivoted about its pivotal connection 204f to the memory socket 204, one of skill in the art will recognize that the latch member 204d may be operated in the same manner.) Once the memory device 208 has been positioned in the memory slot 204a (e.g., such that electrical connectors (not illustrated) on the memory device 208 engage electrical connectors on the memory socket 204), the latch members 204d and 204e may be pivoted about their connections to the memory socket 204 and back towards the latch ends 204b and 204c, respectively, such that the latch members 204d and 204e engage the memory device 208 (e.g., by becoming located in securing channels 208a and 208b defined by the memory device) to secure the memory device 208 to the memory socket 204. One of skill in the art will recognize that memory devices may be coupled to any of the memory sockets (e.g., the memory socket 206) in substantially the same manner as discussed above for the memory socket 204.

As can be seen in FIGS. 2c and 2d, a spacing B must be provided between the latch ends 204c and 206b of the memory sockets 204 and 206, respectively, such that each latch member 204e and 206d may pivot about its connection to its memory socket 204 and 206, respectively, to allow a memory device to be coupled to that memory socket. For example, the spacing B illustrated in FIG. 2c allows the latch member 204e to be pivoted about its connection to the memory socket 204 and away from the latch end 204c without engaging or otherwise being interfered with by the latch member 206d (when the latch member 206d has not been pivoted away from the latch end 206d). Thus, the spacing B attempts to minimize the spacing between memory sockets in the convention memory device latching system 200. However, while the spacing B attempts to minimize the volume occupied by the conventional memory device latching system 200 and thus helps to maximize the number of components that may be provided in the IHS, it also introduces several disadvantages. For example, in the embodiment illustrated in FIG. 2c, the latch member 206d may not be pivoted about its connection to the memory socket 206b while the latch member 204e has been pivoted about its connection to the memory socket 204, as the spacing B only provides enough volume to allow for the pivoting of one of the latch members 204e and 206d. Thus, with regard to adjacent memory sockets such as the memory sockets 204 and 206, only one memory socket may be prepared to accept a memory device at a time. Furthermore, as illustrated in FIG. 2d, the latch members 204e and 206d may interfere with each other such that the latch member 204e becomes ‘stuck’ under the latch member 206d. Thus, while attempting to provide a minimal spacing between memory sockets in a conventional memory device latching system may provide some benefits to the IHS, that spacing B is still limited by the physical requirements of the convention memory latching system and tends to introduce several disadvantages with regard to the use of the conventional memory device latching system.

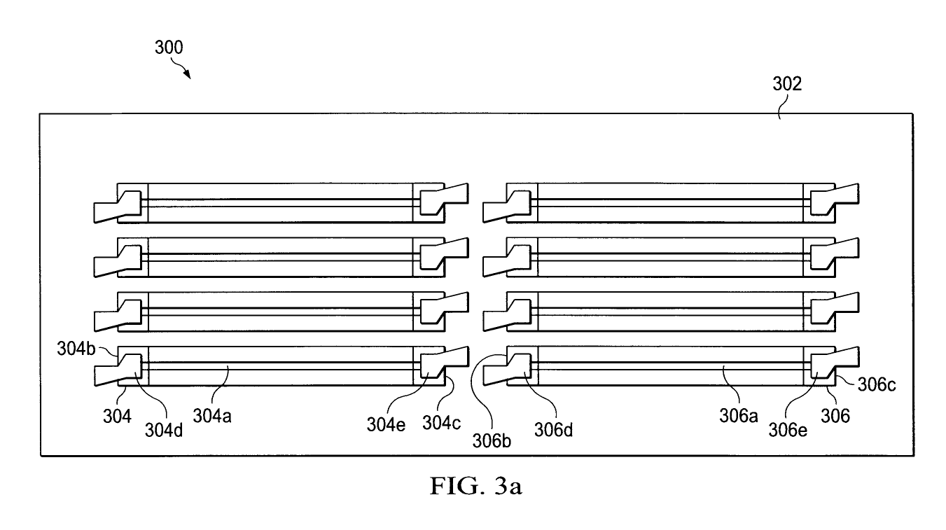

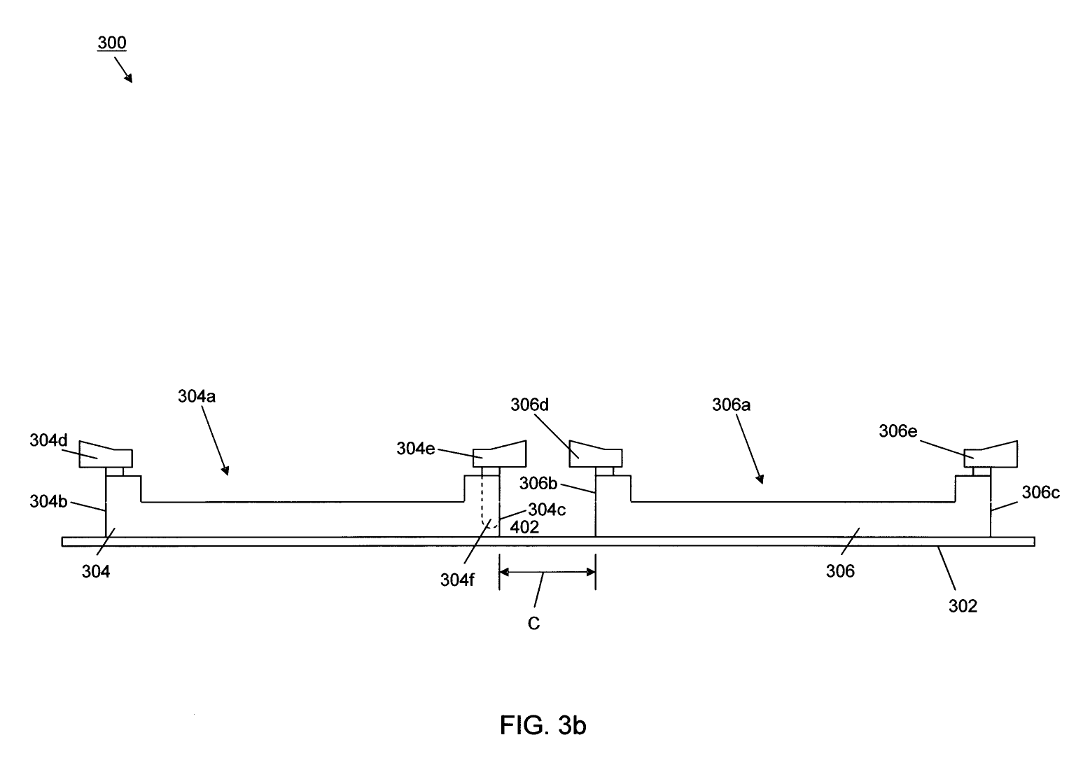

Referring now to FIGS. 3a and 3b, a IHS component latching system 300 is illustrated that overcomes the deficiencies of conventional systems such as the conventional memory device latching system 200 described above. While the IHS component latching system 300 is illustrated as a memory device latching system, the teachings of the present disclosure may be applied to a wide variety of IHS component coupling systems other than those that couple memory devices to IHSs. In an embodiment, the IHS component latching system 300 may be included in the IHS 100 described above with reference to FIG. 1. The IHS component latching system 300 includes a circuit board 302. A plurality of IHS component coupling devices are mounted to the circuit board 302. In the illustrated embodiment, the IHS component coupling devices include a plurality of memory sockets of which memory sockets 304 and 306 are exemplary. The memory socket 304 defines a memory slot 304a and includes a pair of opposing latch ends 304b and 304c located on opposite sides of the memory slot 304a. The memory socket 306 defines a memory slot 306a and includes a pair of opposing latch ends 306b and 306c located on opposite sides of the memory slot 306a.

A latch member 304d is pivotally coupled to the memory socket 304 on the latch end 304b, and a latch member 304e is pivotally coupled (e.g., about a pivotal connection 304f) to the memory socket 304 on the latch end 304c. A latch member 306d is pivotally coupled to the memory socket 306 on the latch end 306b, and a latch member 306e is pivotally coupled to the memory socket 306 on the latch end 306c. One of skill in the art will recognize that the memory sockets 304 and 306 may include several features that have not been illustrated or described for clarity of discussion such as, for example, electrical connections on the memory sockets 304 and 306 adjacent the memory slots 304a and 306a, respectively, that are operable to electrically couple a memory device to components on the circuit board 302 such as a processor.

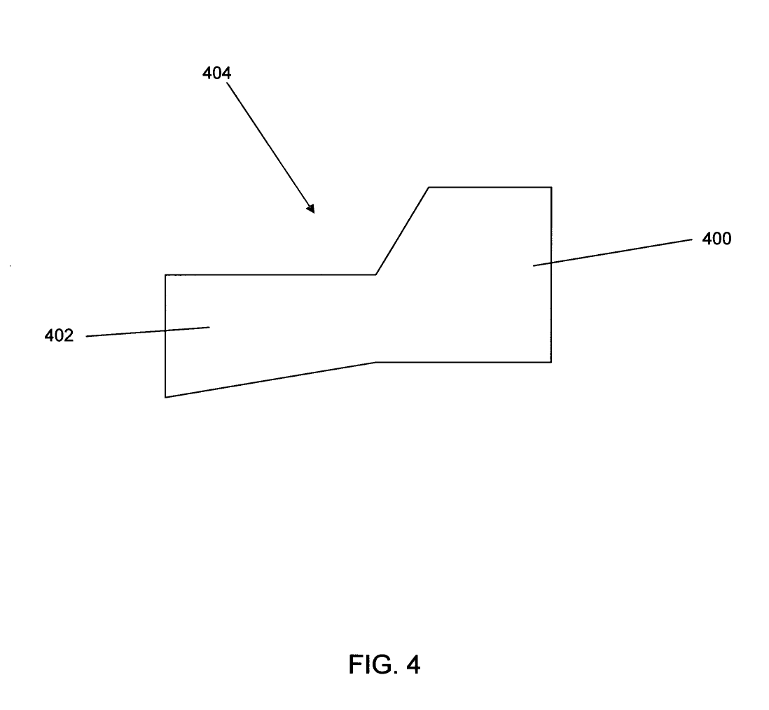

Referring now to FIGS. 3a, 3b, and 4, a latch member 400 is illustrated that may be any of the latch members on the memory sockets (e.g., the latch members 304d, 304e, 306d, and 306e, discussed above). The latch member 400 includes an actuation member 402 and defines a latch member channel 404 that, in the illustrated embodiment, is located immediately adjacent the actuation member 402. In an embodiment, the latch member 400 may be provided as the latch members on each of the memory sockets in order to allow for the nesting of adjacent latch members, discussed in further detail below. Thus, in one embodiment, each of the latch members on the memory sockets may have the same physical dimensions (i.e., the dimensions of the latch member 400.)

Referring now to FIGS. 3a, 3b, 4, and 5a, a method 500 for coupling IHS components to an IHS is illustrated. While the method 500 is described below with regard to the coupling of memory devices to memory sockets, one of skill in the art will recognize that the coupling of a variety of IHS components to an IHS will fall within the scope of the present disclosure. The method 500 begins at block 502 where a first IHS component coupling device including a first latch member and a second IHS component coupling device including a second latch member are provided. In an embodiment, the first IHS component coupling device including the first latch member is provided as the memory socket 304 with the latch member 304e, and the second IHS component coupling device including the second latch member is provided as the memory socket 306 and the latch member 306d. As can been seen in FIGS. 3a and 3b, the memory sockets 304 and 306 are mounted to the circuit board 302 such that the latch end 304c on the memory socket 304 is located adjacent the latch end 306b on the memory socket 306 and the latch ends 304c and 306b are separate by a spacing C.

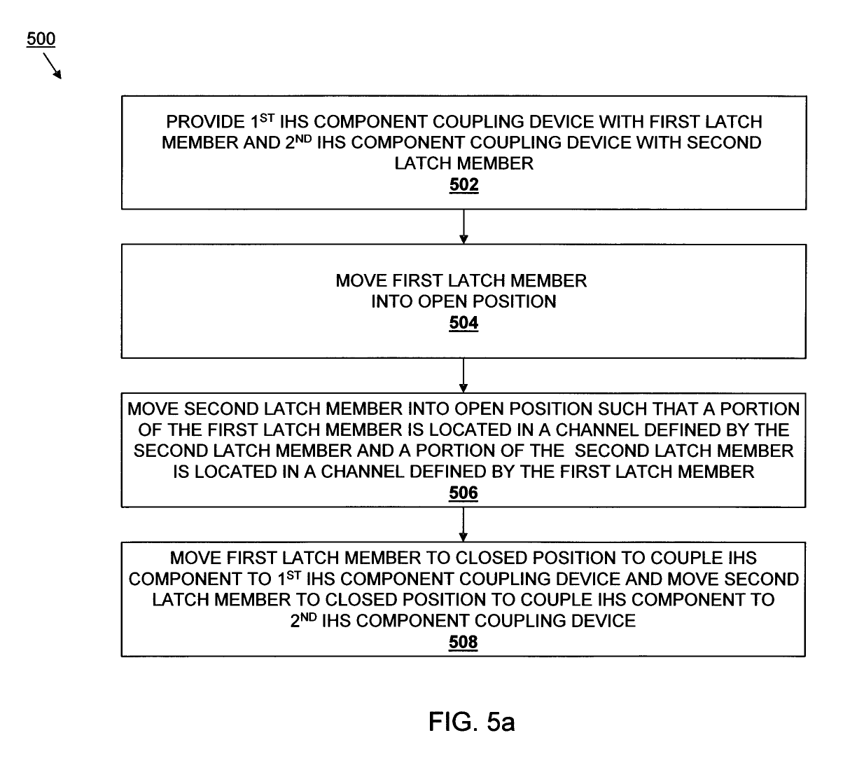

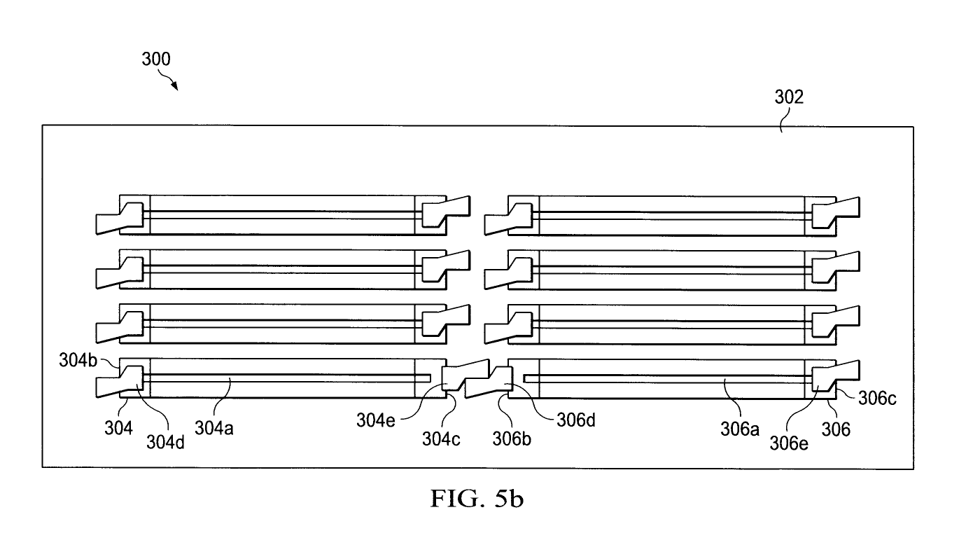

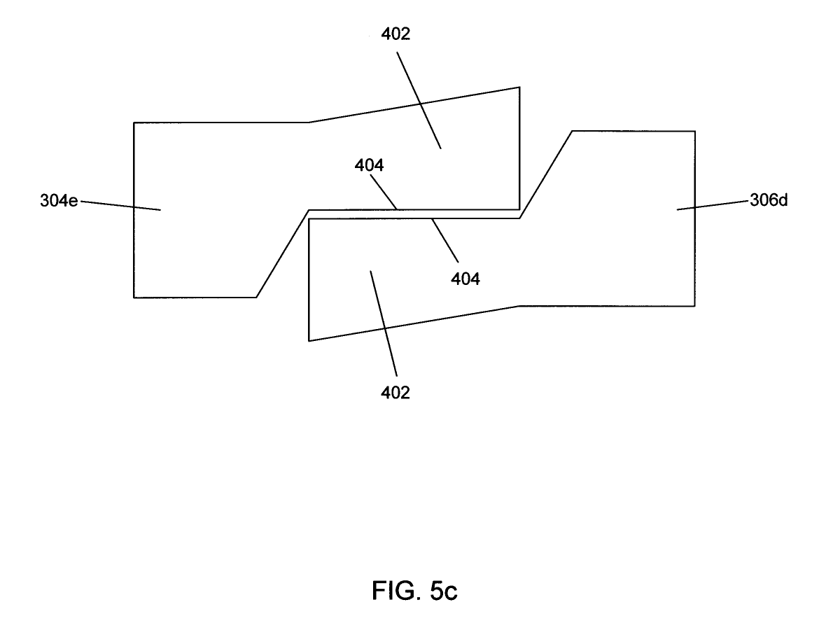

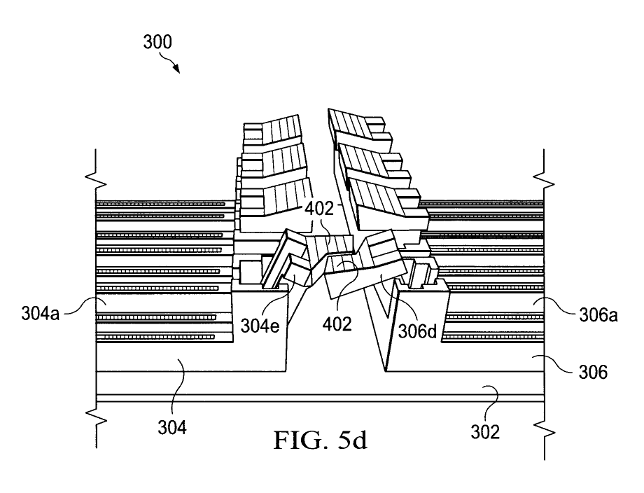

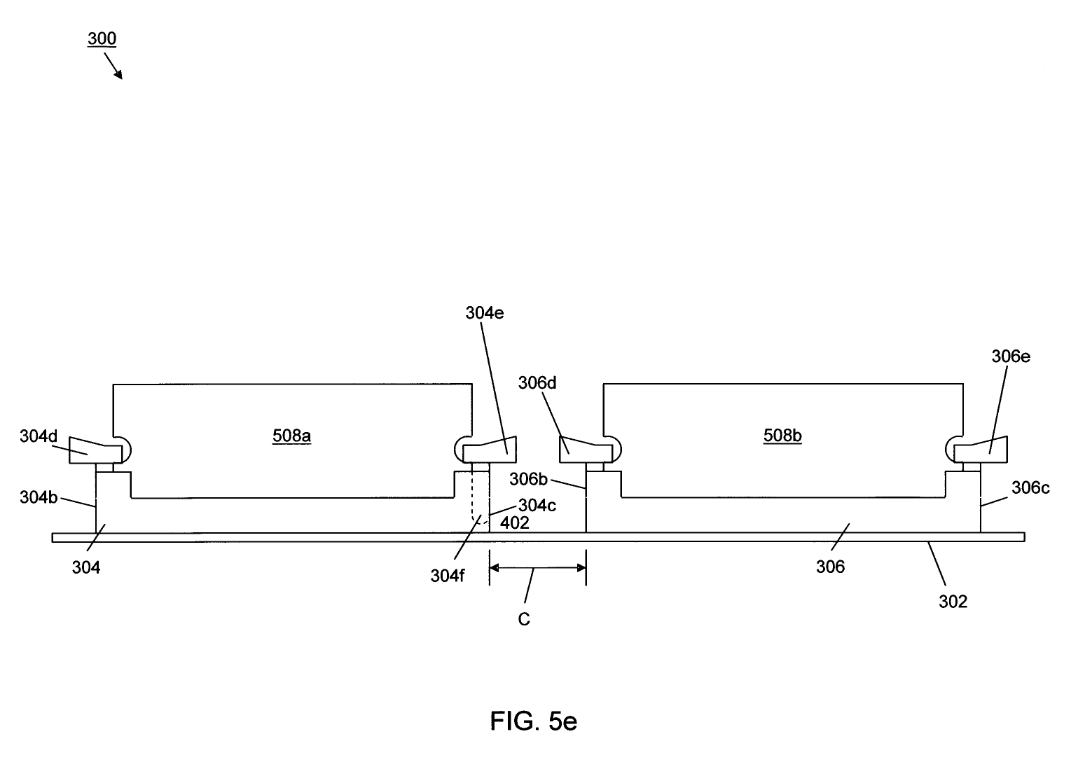

The method 500 then proceeds to block 504 where the first latch member is moved into an open position. In an embodiment, the latch member 304e may be pivoted about the pivotal connection 304f to the memory socket 304 such that the latch member 304e moves relative to the latch end 304c from a closed position, illustrated in FIGS. 3a and 3b, to an open position, illustrated in FIGS. 5b and 5c. One of skill in the art will recognize that, with the latch member 304e extending from the latch end 304c and in the open position (and along with the latch member 304d in a similar open position), a memory device may be positioned in the memory slot 304a, and the latch member 304e may then operate to secure a memory device in the memory socket 304 in the closed position, discussed in further detail below.

Referring now to FIGS. 5a, 5b, 5c, and 5d, the method 500 then proceeds to block 506 where the second latch member is moved into an open position such that a portion of the first latch member is located in a channel defined by the second latch member and a portion of the second latch member is located in a channel defined by the first latch member. In an embodiment, the latch member 306d may be pivoted about its pivotal connection to the memory socket 306 such that the latch member 306d moves relative to the latch end 306b from a closed position, illustrated in FIGS. 3a and 3b, to an open position, illustrated in FIGS. 5b and 5c. One of skill in the art will recognize that, with the latch member 306d extending from the latch end 306b and in the open position (and along with the latch member 306e in a similar open position), a memory device may be positioned in the memory slot 306a, and the latch member 306d may then operate to secure a memory device in the memory socket 306 in the closed position, discussed in further detail below. Furthermore, as can be seen in FIGS. 5b, 5c, and 5d, with the latch members 304e and 306d in their respective open positions, the actuation member 402 on the latch member 304e/400 is positioned in the latch member channel 404 on the latch member 306d/400, and the actuation member 402 on the latch member 306d/400 is positioned in the latch member channel 404 on the latch member 304e/400. In the illustrated embodiment, a majority of the actuation member 402 on the latch member 304e/400 is positioned in the latch member channel 404 on the latch member 306d/400, and a majority of the actuation member 402 on the latch member 306d/400 is positioned in the latch member channel 404 on the latch member 304e/400. However, other embodiments having other latch member geometries may provide for the nesting of adjacent latch members differently while remaining within the scope of the present disclosure.

As discussed above, the latch members on the memory sockets in the IHS component latching system 300 allow for the nesting of adjacent latch members on adjacent memory sockets. As also discussed above, each of the latch members on the plurality of memory sockets may be identical, as illustrated in FIG. 5b, which can reduces costs associated with providing different latch members and the need to assemble the different latch members on specific sides of the memory sockets. However, in other embodiments, latch members capable of nesting may only be provided on the latch ends of memory sockets that are adjacent. Furthermore, while a specific embodiment of a nesting latch member has been illustrated and described, one of skill in the art will recognize that a variety of different latch member structures may provide for the nesting of latch members while remaining within the scope of the present disclosure. For example, while the latch member channel and the actuation member on each latch member have been illustrated as being oriented side-by-side, a variety of other dimensions and geometries will allow for the movement of the latch members away from the latch ends of their adjacent memory sockets and past their adjacent latch members (e.g., such that the both of the adjacent latch member are positioned in a common volume that is located between the memory sockets and oriented perpendicularly to the memory sockets), providing the adjacent memory sockets that are positioned closer together than is conventionally possible while still allowing for the latch members to be moved to an open position that enables a memory device to be positioned in a memory slot defined by their memory socket without the latch members colliding, catching, and/or otherwise interfering with each other. Furthermore, the nesting may allow movement of each adjacent latch member that is sufficient to allow a memory device to be positioned in each adjacent memory socket. Thus, both adjacent latch members may be moved to an open position at the same time, and memory devices may be positioned in the memory sockets without having to move either latch member to a closed positioned.

The method 500 then proceeds to block 508 where the first latch member is moved to a closed position to couple an IHS component to the first IHS component coupling device, and the second latch member is moved to a closed position to couple an IHS component to the second IHS component coupling device. In an embodiment, a memory device 508a may be provided as the IHS component and may be positioned in the memory slot 304a on the memory socket 304 when the latch members 304d and 304e are in their open positions. The latch members 304d and 304e may be moved from the open position (e.g., the open position of the latch member 304e illustrated in FIGS. 5b and 5d) to a closed positioned illustrated in FIG. 5e in order to couple and secure the memory device 508a to the memory socket 304. Furthermore, a memory device 508b may be provided as the IHS component and may be positioned in the memory slot 306a on the memory socket 306 when the latch members 306d and 306e are in their open positions. The latch members 306d and 306e may be moved from the open position (e.g., the open position of the latch member 306d illustrated in FIGS. 5b and 5d) to a closed positioned illustrated in FIG. 5e in order to couple and secure the memory device 508b to the memory socket 306.

Thus, an IHS component latching system has been described that provides for the nesting of latches on IHS component coupling devices that are positioned adjacent each other. Such nesting allows for the IHS component coupling devices to be positioned closer to each other than has been possible in conventional systems due to interference between the latches. In an experimental embodiment utilizing memory sockets as the IHS component coupling devices, the spacing between pairs of memory sockets in a conventional memory device latching system (e.g., the spacing B between the memory sockets 204 and 206 illustrated in FIG. 2c) was reduced using the memory device latching system of the present disclosure (e.g., to the spacing C between the memory sockets 304 and 306 illustrated in FIG. 3b) such that the pair of memory sockets of the present disclosure occupied 200 square millimeters less of circuit board area. One of skill in the art will recognize that such space savings can become significant when multiplied over a plurality of memory socket pairs such as those illustrated in FIG. 5b.

Although illustrative embodiments have been shown and described, a wide range of modification, change and substitution is contemplated in the foregoing disclosure and in some instances, some features of the embodiments may be employed without a corresponding use of other features. Accordingly, it is appropriate that the appended claims be construed broadly and in a manner consistent with the scope of the embodiments disclosed herein.

What is claimed is:

1. An information handling system (IHS) component latching system, comprising:
a first IHS component coupling device having a first latch end including a first latch member, wherein the first latch member includes a first latch actuation member and defines a second latch member channel; and
a second IHS component coupling device having a second latch end including a second latch member, wherein the second latch member includes a second latch actuation member and defines a first latch member channel;
wherein, with the first latch end on the first IHS component coupling device located adjacent the second latch end on the second IHS component coupling device, the first latch member is operable to move relative to the first latch end and the second latch member is operable to move relative to the second latch end such that at least a portion of the first latch actuation member is located in the first latch member channel and at least a portion of the second latch actuation member is located in the second latch member channel.

2. The system of claim 1, further comprising:
a circuit board, wherein the first IHS component coupling device and the second IHS component coupling device are mounted to the circuit board such that the first latch end is located adjacent the second latch end.

3. The system of claim 1, wherein the first latch member is pivotally coupled to the first IHS component coupling device and operable to pivot such that the first latch member extends from the first latch end, and wherein the second latch member is pivotally coupled to the second IHS component coupling device and operable to pivot such that the second latch member extends from the second latch end.

4. The system of claim 1, wherein the second latch member channel is defined immediately adjacent the first latch actuation member, and wherein the first latch member channel is defined immediately adjacent the second latch actuation member.

5. The system of claim 1, wherein the first latch member and the second latch member include the same physical dimensions.

6. The system of claim 1, wherein with the first latch member moved relative to the first latch end and the second latch member moved relative to the second latch end, a majority of the first latch actuation member is located in the first latch member channel and a majority of the second latch actuation member is located in the second latch member channel.

7. The system of claim 1, wherein with at least a portion of the first latch actuation member located in the first latch member channel and at least a portion of the second latch actuation member located in the second latch member channel, the first IHS component coupling device is operable to receive a first IHS component and the second IHS component coupling device is operable to receive a second IHS component.

8. An information handling system, comprising:
a processor;
a plurality of memory devices coupled to the processor through respective memory sockets, wherein the memory sockets include:
a first memory socket having a first latch end including a first latch member, wherein the first latch member includes a first latch actuation member and defines a second latch member channel; and
a second memory socket having a second latch end including a second latch member, wherein the second latch member includes a second latch actuation member and defines a first latch member channel;
wherein the first latch end is located adjacent the second latch end and the first latch member is operable to move relative to the first latch end and the second latch member is operable to move relative to the second latch end such that at least a portion of the first latch actuation member is located in the first latch member channel and at least a portion of the second latch actuation member is located in the second latch member channel.

9. The IHS of claim 8, further comprising:
a circuit board, wherein the first memory socket and the second memory socket are mounted to the circuit board such that the first latch end is located adjacent the second latch end.

10. The IHS of claim 8, wherein the first latch member is pivotally coupled to the first memory socket and operable to pivot such that the first latch member extends from the first latch end, and wherein the second latch member is pivotally coupled to the second memory socket and operable to pivot such that the second latch member extends from the second latch end.

11. The IHS of claim 8, wherein the second latch member channel is defined immediately adjacent the first latch actuation member, and wherein the first latch member channel is defined immediately adjacent the second latch actuation member.

12. The IHS of claim 8, wherein the first latch member and the second latch member include the same physical dimensions

13. The IHS of claim 8, wherein with the first latch member moved relative to the first latch end and the second latch member moved relative to the second latch end, a majority of the first latch actuation member is located in the first latch member channel and a majority of the second latch actuation member is located in the second latch member channel.

14. The IHS of claim 8, wherein with at least a portion of the first latch actuation member located in the first latch member channel and at least a portion of the second latch actuation member located in the second latch member channel, the first memory socket is operable to receive a first memory device and the second memory socket is operable to receive a second memory device.

15. A method for coupling IHS components to an IHS, comprising:
providing a first IHS component coupling device having a first latch member and a second IHS component coupling device having a second latch member;
moving the first latch member relative to the first IHS component coupling device and into an open position using a first latch actuation member such that a first IHS component may be received by the first IHS component coupling device;
moving the second latch member relative to the second IHS coupling device and into an open position using a second latch actuation member such that a second IHS component may be received by the second IHS component coupling device, wherein with the first latch member and the second latch member in the open positions, at least a portion of the first latch actuation member is located in a first latch member channel defined by the second latch member and at least a portion of the second latch actuation member is located in a second latch member channel defined by the first latch member;
moving the first latch member to a closed position to couple the first IHS component to the first IHS component coupling device; and
moving the second latch member to a closed position to couple the second IHS component to the second IHS component coupling device.

16. The method of claim 15, wherein the first latch member is pivotally coupled to the first IHS component coupling device and operable to pivot such that the first latch member extends from an end of the first IHS component coupling device, and wherein the second latch member is pivotally coupled to the second IHS component coupling device and operable to pivot such that the second latch member extends from an end of the second IHS component coupling device.

17. The method of claim 15, wherein the second latch member channel is defined immediately adjacent the first latch actuation member, and wherein the first latch member channel is defined immediately adjacent the second latch actuation member.

18. The method of claim 15, wherein the first latch member and the second latch member include the same physical dimensions.

19. The method of claim 15, wherein with the first latch member and the second latch member moved into the open positions, a majority of the first latch actuation member is located in the first latch member channel and a majority of the second latch actuation member is located in the second latch member channel.

20. The method of claim 15, wherein the first IHS component coupling device and the second IHS component coupling device are mounted to the circuit board such that the first latch member is located adjacent the second member.
